(19) United States
(12) Patent Application Publication
(10) Pub. No.: US 2012/0280291 A1
(43) Pub. Date: Nov. 8, 2012

(54) SEMICONDUCTOR DEVICE INCLUDING GATE OPENINGS

(76) Inventors: Jae-kyu Lee, Gyeonggi-do (KR); Sang-hyun Hong, Seoul (KR)

(21) Appl. No.: 13/463,197

(22) Filed: May 3, 2012

(30) Foreign Application Priority Data
May 4, 2011 (KR) 10-2011-0042633

(51) Int. Cl. H01L 29/78

(52) U.S. Cl. 257/288; 257/E29.255

(57) ABSTRACT

According to example embodiments, a semiconductor device includes a substrate, a device isolation layer over the substrate that defines an active region of the substrate, a gate electrode crossing over the active region in between a source region and a drain region of the active region. The gate electrode defines at least one gate opening. The at least one gate opening may expose a portion of a boundary between the active region and the device isolation layer.

### CROSS-REFERENCE TO RELATED APPLICATIONS

This application claims priority under 35 U.S.C.§119 to Korean Patent Application No. 10-2011-0042633, filed on May 4, 2011, in the Korean Intellectual Property Office, the disclosure of which is incorporated herein in its entirety by reference.

### BACKGROUND

1. Field

Some example embodiments of inventive concepts relate to a semiconductor device, and more particularly, to a semiconductor device for obtaining a high integration density.

2. Related Art

Along with industrial and multimedia development, semiconductor devices used in computers, mobile equipment, or the like are highly integrated and have high performance. In line with the increase in the integration density of semiconductor devices, the number of design rules for components of the semiconductor devices may be reduced. In particular, with regard to a semiconductor device including many transistors, the length of a gate, which is a reference of design rules, is reduced. Accordingly, the length of a channel is reduced.

### SUMMARY

Some example embodiments of inventive concepts relate to semiconductor devices for obtaining a high integration density and/or improved reliability.

According to an example embodiment of inventive concepts, a semiconductor device includes a substrate, a device isolation layer over the substrate, and a gate electrode crossing over the active region in between a source region and a drain region of the active region. The device isolation layer defines an active region in the substrate. The gate electrode defines at least one gate opening that exposes a portion of a boundary between the active region and the device isolation layer.

The semiconductor device may further include an insulating material filling the gate opening.

The semiconductor device may further include spacers on at least two lateral surfaces of the gate electrode and a lateral surface defining the gate opening.

The spacers may cover an upper surface of the active region that is exposed by the at least one gate opening.

The gate opening may be a hole through the gate electrode.

The gate electrode may define two gate openings. The two gate openings may be symmetrically positioned with respect to the active region on two boundaries between the device isolation layer and the active region.

The gate electrode may define at least one gate opening on at least one lateral surface of the gate electrode.

The gate electrode may define gate openings on opposite lateral surfaces of the gate electrode. The gate openings may be over two boundaries between the device isolation layer and the active region.

The gate electrode may define a plurality of gate openings along a boundary between the active region and the device isolation layer.

The active region exposed by the gate opening may include an impurity region including impurities.

The impurity region may include impurities with a different conductive type than a conductivity type of impurities in the source region and the drain region.

The device isolation layer may include a trench liner on a lateral wall of the substrate adjacent to the active region. The trench liner may include a nitride.

The semiconductor device may further include a gate dielectric layer between the active region and the gate electrode.

According to an example embodiment of inventive concepts, a semiconductor device includes a substrate, a device isolation layer over the substrate, a gate electrode crossing over a channel region of the active region in between a source region and a drain region of the active region. The device isolation layer defines an active region in the substrate. The channel region includes an upper surface having at least two different channel widths. The at least two different channel widths extend in a direction parallel to an elongated direction of the electrode.

The gate electrode defines at least one gate opening that exposes a portion of a boundary between the active region and the device isolation layer. The channel region may have a smaller channel width in a region where the at least one gate opening is defined that in a remaining region of the channel region that is not under where the at least one gate opening is defined.

According to example embodiments, a semiconductor device includes a substrate and a gate electrode. The substrate includes at least one active region defined by an isolation layer pattern. The active region extends lengthwise in a first direction and widthwise in a second direction. The gate electrode extends in the second direction over the active region in between a source and a drain region of the active region. The gate electrode defines at least one gate opening. The at least one gate opening exposes a part of the active region.

The at least one gate opening may be defined by at least one internal lateral surface of the gate electrode. The at least one gate opening may expose a portion of a boundary between the active region and the device isolation layer pattern.

The at least one gate opening may be defined by at least one external lateral surface of the gate electrode. The at least one gate opening may expose a portion of a boundary between the active region and the device isolation layer pattern.

The gate electrode may define at least two gate openings that are spaced apart in the first direction. The at least two gate openings may expose a first a second portion of a boundary between the active region and the device isolation layer pattern.

The gate electrode may define at least two gate openings that are spaced apart in the second direction. The at least two gate openings may expose a portion of a first boundary and a portion of a second boundary between the active region and the device isolation layer pattern.

### BRIEF DESCRIPTION OF THE DRAWINGS

Example embodiments of inventive concepts will be more clearly understood from the following brief description taken in conjunction with the accompanying drawings, in which like reference characters refer to the same parts throughout the different views. The drawings are not necessarily to scale, emphasis instead being placed upon illustrating the principles of inventive concepts. In the drawings:

FIG. 1 is a schematic layout of a semiconductor device according to a first example embodiment of inventive concepts;

FIGS. 2A and 2B are cross-sectional views of a semiconductor device taken along lines II-A-II-A′ and II-B-II-B′ of FIG. 1, respectively;

FIGS. 3A through 3G are cross-sectional views for describing a method of manufacturing the semiconductor device of FIG. 1, according to a first example embodiment of inventive concepts;

FIG. 4 is a schematic layout of a semiconductor device according to a second example embodiment of inventive concepts.

FIGS. 5A and 5B are cross-sectional views of a semiconductor device taken along lines V-A-V-A′ and V-B-V-B′ of FIG. 4, respectively;

FIG. 6 is a schematic layout of a semiconductor device according to a third example embodiment of inventive concepts.

FIGS. 7A and 7B are cross-sectional views of a semiconductor device taken along lines VII-B-VII-B′ and VII-B-VII-B′ of FIG. 6, respectively.

FIG. 8 is a schematic layout of a semiconductor device according to a fourth example embodiment of inventive concepts;

FIGS. 9A and 9B are cross-sectional views of a semiconductor device taken along lines IX-A-IX-A′ and IX-B-IX-B′ of FIG. 8, respectively;

FIG. 10 is a schematic layer of a semiconductor device according to a fifth example embodiment of inventive concepts.

FIG. 11 is a cross-sectional of a semiconductor device according to a fifth example embodiment of inventive concepts; and

FIG. 12 is a graph showing a simulation result about characteristics of a semiconductor device according to an example embodiment of inventive concepts.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scopes of example embodiments of inventive concepts to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

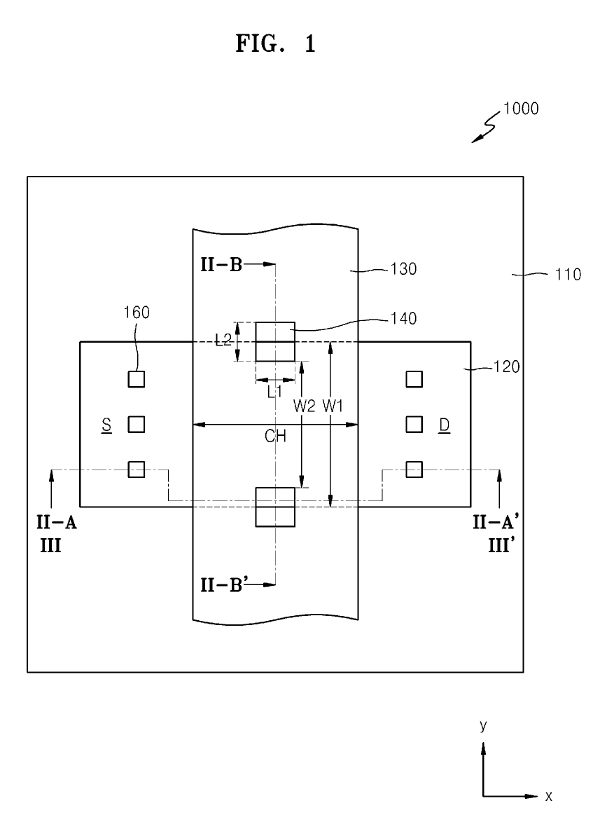

FIG. 1 is a schematic layout of a semiconductor device 1000 according to an embodiment of the inventive concept.

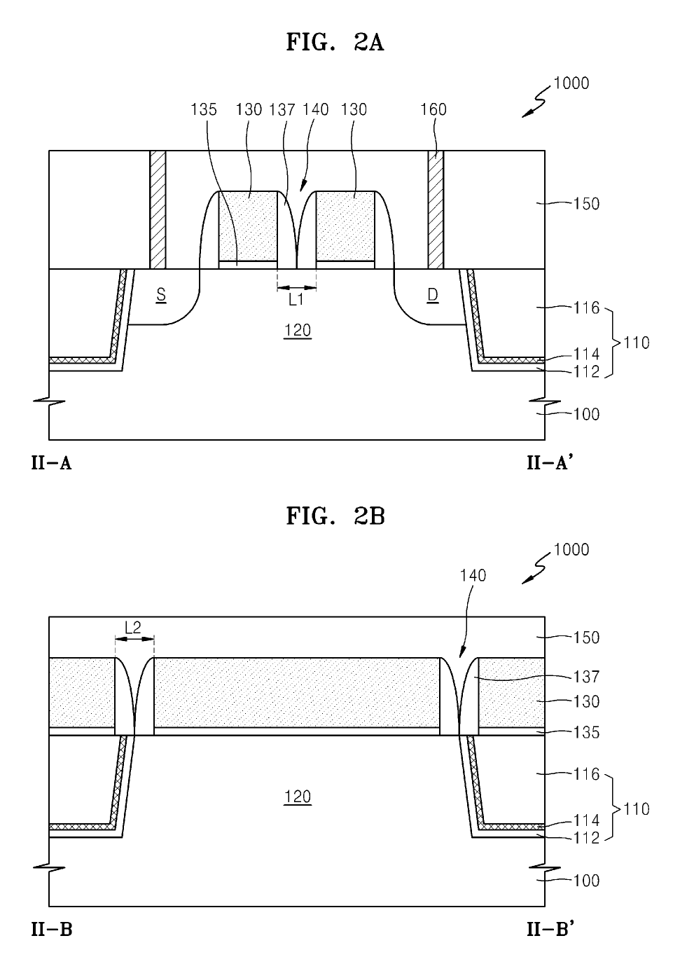

FIGS. 2A and 2B are cross-sectional views of semiconductor device 1000 taken along lines II-A-II-A′ and II-B-II-B′ of FIG. 1, respectively.

Referring to FIGS. 1, 2A, and 2B, the semiconductor device 1000 includes an active region 120 that is defined by a device isolation layer 110 in a substrate 100. In addition, the semiconductor device 1000 may include a gate electrode 130 disposed on the substrate 100 and including a gate opening 140 formed therein, and contact plugs 160 formed on a source region S and a drain region D that are formed at two sides of the gate electrode 130. The semiconductor device 1000 may constitute a circuit unit of a memory device such as a flash memory or a dynamic random access memory (DRAM), but example embodiments are not limited thereto.

The substrate 100 may have a main surface that extends in x-axis and y-axis directions. The substrate 100 may include a semiconductor material, for example, a Group IV semiconductor, a Group III to V compound semiconductor, or a Group II to VI oxide semiconductor, but example embodiments are not limited thereto. For example, the Group IV semiconductor may include silicon, germanium, or silicon-germanium, but example embodiments are not limited thereto. The substrate 100 may be a bulk wafer, or an epitaxial layer, but example embodiments are not limited thereto. The substrate 100 may include a well region (not shown) that is formed by injecting impurities.

The device isolation layer 110 may have a shallow trench isolation (STI) structure, and may include a first insulating layer 112, a trench liner 114, and a second insulating layer 116, which are sequentially formed in the substrate 100. The first insulating layer 112, the trench liner 114, and the second insulating layer 116 may each be formed of a dielectric material such as an oxide, a nitride, or a combination thereof. For example, the first insulating layer 112 may be a buffer oxide layer. The trench liner 114 may include a nitride or an oxynitride. In addition, the second insulating layer 116 may include at least one selected from the group consisting of TOnen SilaZene (TOSZ), a high temperature oxide (HTO), a high density plasma (HDP) material, tetra ethyl ortho silicate (TEOS), boron-phosphorus silicate glass (BPSG), and undoped silicate glass (USG). However, example embodiments are not limited thereto.

The active region 120 may have an island shape defined by the device isolation layer 110 in the substrate 100. The active region 120 may include the source region S and the drain region D that are formed at the two sides of the gate electrode 130. The source region S and the drain region D may be formed in the active region 120 to have a desired (or alternatively predetermined) depth, and may each be an impurities region including impurities. The impurities may be p-type impurities, for example, boron (B), aluminum (Al), or gallium (Ga), but example embodiments are not limited thereto.

The gate electrode 130 may be formed on the substrate 100, and may extend in one direction, for example, the y-axis direction so as to cross the active region 120. The gate electrode 130 may include polysilicon, metal silicide, or metal such as tungsten (W), but example embodiments are not limited thereto. The gate electrode 130 may include a single layer or a composite layer. For example, the gate electrode 130 may include a metal silicide layer formed in an upper portion thereof. A gate dielectric layer 135 may be interposed between the gate electrode 130 and the substrate 100. For example, the gate dielectric layer 135 may include a dielectric such as silicon oxide, but example embodiments are not limited thereto. Spacers 137 may be disposed on lateral walls of the gate electrode 130. The spacers 137 may include, for example, silicon nitride or silicon oxide, but example embodiments are not limited thereto.

The gate opening 140 may be formed through the gate electrode 130 in the gate electrode 130. The gate opening 140 may be formed on a boundary between the device isolation layer 110 and the active region 120, which crosses the gate electrode 130. A portion of the device isolation layer 110 and a portion of the active region 120 may be exposed by the gate opening 140. Gate openings 140 may be symmetrically formed with respect to the active region 120 on the boundaries between the device separation layer 110 and the active region 120 that are parallel to each other.

The gate opening 140 may be shaped like a hole. The gate opening 140 may have a first length L1 in the x-axis direction and a second length L2 in the y-axis direction. The first length L1 may be about ¼ to about ½ a channel length CH of the semiconductor device 1000. As described below, the first length L1 may be determined so as to sufficiently exhibit an intermittence effect of a channel region due to intermittence of the gate electrode 130. The second length L2 may be a desired (or alternatively predetermined) length so as to expose the boundary between the device isolation layer 110 and the active region 120, and may be determined so as not to excessively reduce an amount of a current of the semiconductor device 1000.

Due to the gate opening 140, the semiconductor device 1000 may have a channel width that is not uniform. The channel region may be formed in the active region 120 that crosses the gate electrode 130. The channel width may be defined as a length of the channel region, which is measured in the y-axis direction. That is, the semiconductor device 1000 may have a first channel width W1, but may have a second channel width W2 smaller than the first channel width W1 in a region where the gate opening 140 is formed.

The gate opening 140 may be filled and covered with an insulating material. For example, the spacers 137 may be formed on internal walls of the gate opening 140, and an interlayer insulating layer 150 may fill and cover the remaining space. An upper surface of the active region 120, which is exposed by the gate opening 140, may be completely covered by the spacers 137. According to a another example embodiment of inventive concepts, the upper surface of the active region 120, which is exposed by the gate opening 140, may not be completely covered by the spacers 137.

The contact plugs 160 may be formed on the source region S and the drain region D, respectively. The contact plugs 160 are disposed so as to respectively apply voltages to the source region S and the drain region D in order to operate the semiconductor device 1000. The contact plugs 160 may be formed through the interlayer insulating layer 150. In addition, upper portions of the contact plugs 160 may be connected to a wiring line (not shown). In a region that is not shown in diagrams, the gate electrode 130 may also be connected to the wiring line through a separate conductor having a plug shape.

During an operation of the semiconductor device 1000, the channel region is formed on the active region 120 formed below the gate electrode 130. When the semiconductor device 1000 is a PMOS transistor, hot holes that are accelerated in the channel region may generate hot electrons by impact ionization in a depletion region of the drain region D. The hot electrons may be trapped by the gate dielectric layer 135 that is adjacent to the drain region D so as to reduce an effective channel length. In particular, the hot electrons may be trapped by the trench liner 114 in the device isolation layer 110. Thus, a leakage current may be generated along an interface of the active region 120 including the channel region, and thus hot electron induced punchthrough (HEIP) by which a leakage current in an off-state may occur.

In the semiconductor device 1000, the gate opening 140 is formed in the gate electrode 130, and thus the gate electrode 130 may be formed intermittent along the channel region on the boundary between the active region 120 and the device isolation layer 110. Thus, an amount of a current is reduced at an edge of the active region 120, which corresponds to the boundary between the active region 120 and the device isolation layer 110 so that electrons are reduced (and/or prevented) from being trapped by the trench liner 114 by an operation of the semiconductor device 1000, thereby reducing the HEIP.

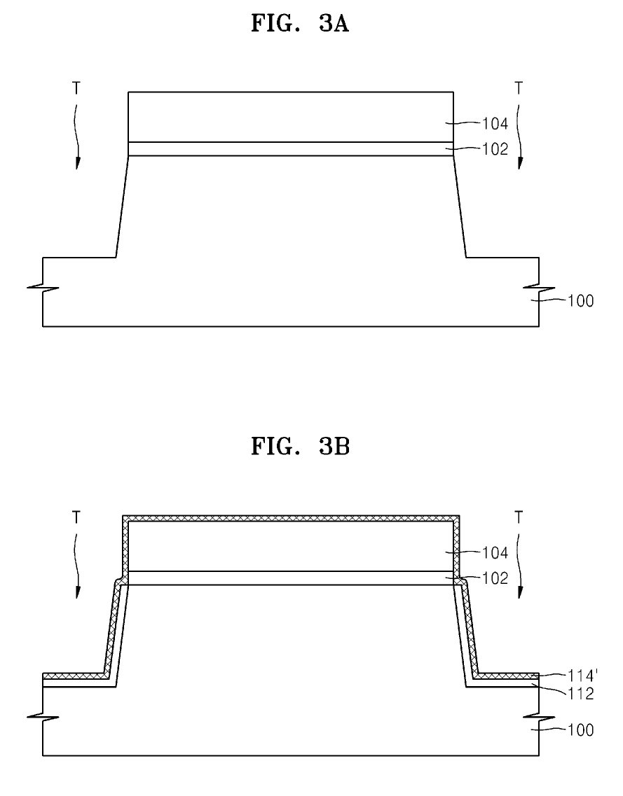

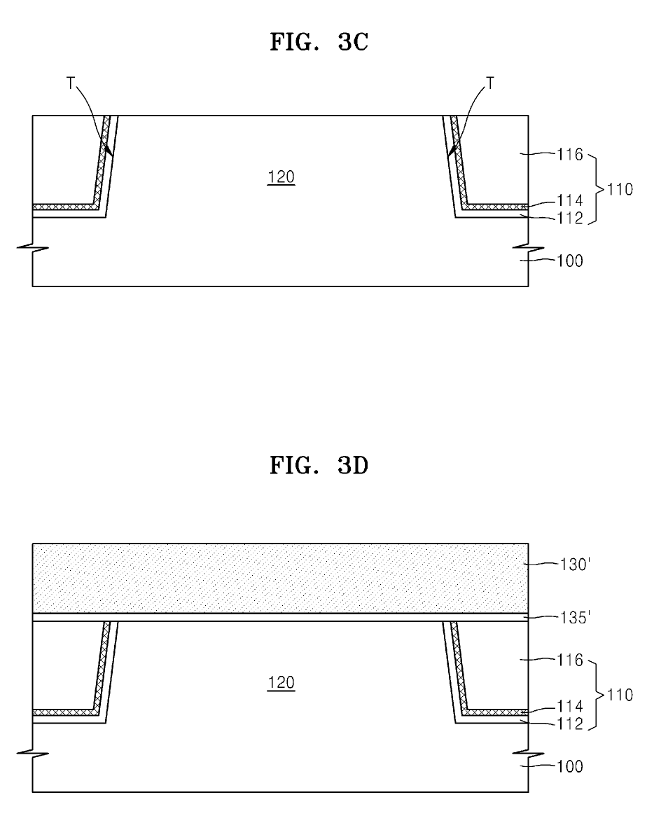

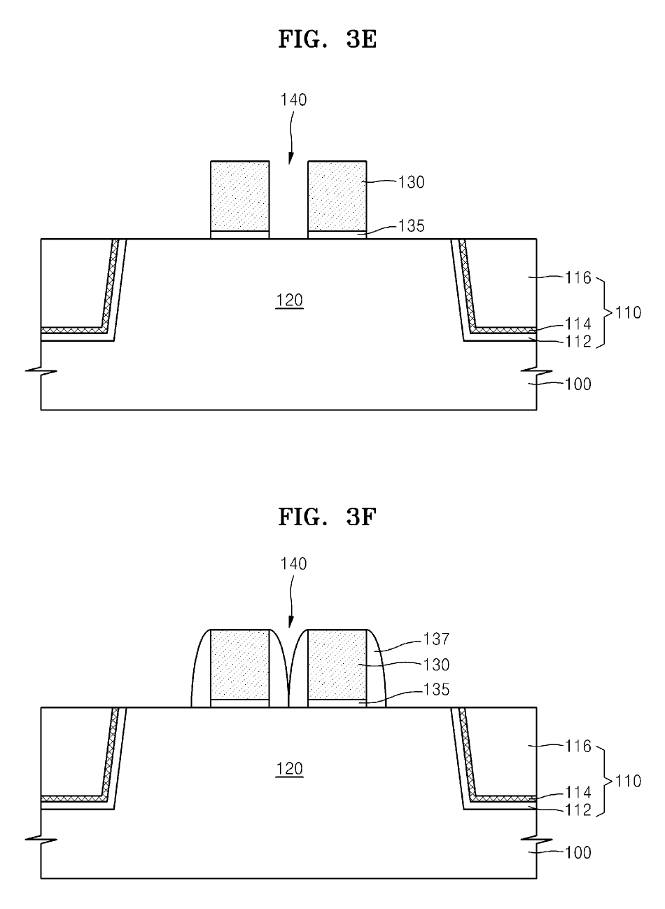

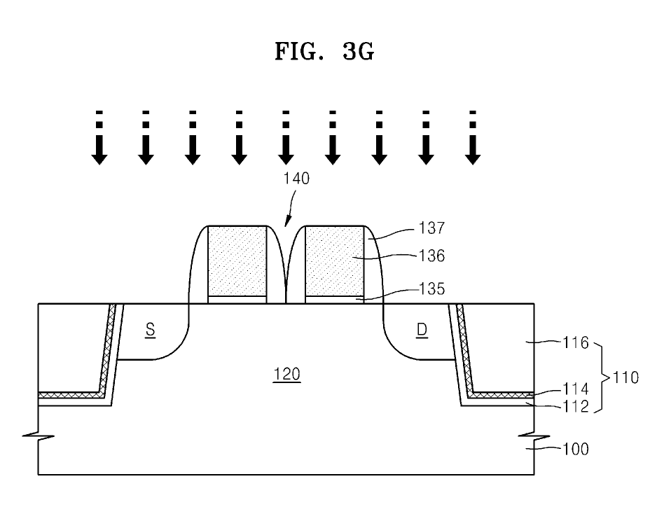

FIGS. 3A through 3G are cross-sectional views for describing a method of manufacturing the semiconductor device 1000 of FIG. 1, according to an example embodiment of inventive concepts. FIGS. 3A through 3G show the semiconductor device 1000 taken along a line III-III′ of FIG. 1.

Referring to FIG. 3A, a pad layer 102 and a mask layer 104 may be disposed on the substrate 100. The pad layer 102 may be, for example, a silicon oxide layer. The pad layer 102 may be formed by using a thermal oxidation process, or a chemical vapor deposition (CVD) process. The pad layer 102 may prevent the substrate 100 from being damaged and may reduce (and/or prevent) a stress from being generated when the mask layer 104 is formed.

The mask layer 104 may include a material with a different etch selectivity form that of each of the substrate 100 and the pad layer 102. Such etch selectivity may be quantitatively expressed by using a ratio of an etch speed of the substrate 100 and the pad layer 102 to an etch speed of the mask layer 104. The mask layer 104 may be a hard mask layer including, for example, a silicon nitride layer. In addition, the mask layer 104 may include a plurality of layers including an organic layer.

The substrate 100 may include a semiconductor material, for example, a Group VI semiconductor. The substrate 100 may be a p-type substrate including a well (not shown) formed by using an ion implantation process.

Then, a device isolation trench T is formed by patterning the pad layer 102 and the mask layer 104 by using a pattern (not shown), for example, a photo resist pattern and then etching the substrate 100. The device isolation trench T may be formed by using an anisotropic etching process, for example, a plasma etching process. A depth of the device isolation trench T may vary according to the characteristics of the semiconductor device 1000. A lateral wall of the device isolation trench T may not be perpendicular to an upper surface of the substrate 100. For example, the closer to a lower surface of the substrate 100, the smaller a width of the device isolation trench T. After forming the device isolation trench T, an ion implantation process for reinforcing insulating characteristics may be selectively performed.

Referring to FIG. 3B, the first insulating layer 112 is formed within the device isolation trench T formed in the substrate 100. The first insulating layer 112 may be a thermal oxidation layer that is formed by using a radical oxidation process using a furnace, or a rapid thermal annealing (RTA) process. The first insulating layer 112 may be formed by depositing an insulating material. In this case, the insulating material may also be deposited on the mask layer 104. The first insulating layer 112 may be formed to have a thickness of, for example, 200 Å or less.

Then, the trench liner film 114′ is formed on the first insulating layer 112. The trench liner film 114′ may include, for example, nitride, and may be formed by low pressure chemical vapor deposition (LPCVD). The trench liner film 114′ may be formed to have a thickness of, for example, 50 Å to 200 Å. If the semiconductor device 1000 is a DRAM device, the semiconductor device 1000 may use a trench liner including a nitride layer formed on a device isolation region in order to improve the refresh characteristics of the semiconductor device 1000. However, in generally when a semiconductor device uses the trench liner including the nitride layer, electrons may be trapped by the trench liner, thereby worsening the HEIP.

Referring to FIG. 3C, a second insulating layer film may be formed on the trench liner film 114 so as to completely fill the device isolation trench T. The second insulating layer film may be formed by using a CVD process. The second insulating layer film may include oxide, for example, any one of HTO, HDP, TEOS, BPSG, and USG. After forming the second insulating layer film, an annealing process for densifying a membrane may be further performed.

Then, a planarization process may be performed. The planarization process may be, for example, a chemical mechanical polishing (CMP) process. Through the planarization process, upper portions of the pad layer 102, the mask layer 104, the trench liner film 114′, and the second insulating layer film, which are formed on the substrate 100, may be removed. As a result of removing upper portions of the trench liner film 114′ and the second insulating layer film during planarization process, the trench liner 114 and second insulating layer result.

After the planarization process is performed, the device isolation layer 110 filled in the device isolation trench T may be completely formed. The device isolation layer 110 may include the first insulating layer 112, the trench liner 114, and the second insulating layer 116. The active region 120 of the substrate 100 may be defined by the device isolation layer 110.

Referring to FIG. 3D, the gate dielectric film 135′ and the gate electrode film 130′ may be formed on the substrate 100. The gate dielectric film 135′ may include silicon oxide (SiO₂), a dielectric material with a high-dielectric constant (k), or a composite layer including silicon oxide (SiO₂) and silicon nitride (SiN). In this case, the material with a high-k refers to a dielectric material having a higher dielectric constant than silicon oxide (SiO₂). The gate electrode film 130′ may include polysilicon or metal such as tungsten (W), but example embodiments are not limited thereto.

Referring to FIG. 3E, the gate dielectric film 135′ and the gate electrode film 130′ are patterned to form the gate dielectric layer 135 and the gate electrode 130 respectively. A mask layer that is not shown in diagrams, for example, a photo resist layer is formed, and then an exposed portion of the gate electrode film 130′ and the gate dielectric film 135′ formed below the an exposed portion of the gate electrode film 130′ may be removed by an etching process.

The gate opening 140 is formed by using the etching process. The gate opening 140 is formed through the gate electrode 130, and the gate electrode 130 may correspond to an internal wall of the gate opening 140. In the process, an upper surface of the active region 120 may be exposed on a lower surface of the gate opening 140. According to another example embodiment of inventive concepts, a portion of the gate dielectric layer 135 may remain on the lower surface of the gate opening 140.

According to the first example embodiment, the gate opening 140 may be formed together with the gate electrode 130 by using an etching process during formation of the gate electrode 130. Selectively, the gate opening 140 may be formed by removing a portion of the gate electrode 130 by using a separate process.

Referring to FIG. 3F, the spacers 137 may be formed on two lateral surfaces (e.g., external walls, but not limited thereto) of the gate electrode 130 and an internal wall of the gate opening 140. The spacers 137 may include an insulating material, for example, silicon oxide or silicon nitride, but example embodiment are not limited thereto. The spacers 137 may be formed by depositing an insulating material and performing an etch-back process so as to expose upper surfaces of the gate electrode 130, the active region 120 and the device isolation layer 110.

The spacers 137 may be formed to cover an upper surface of the active region 120, which is exposed by the gate opening 140 within the gate opening 140. A thickness of spacers 137 may be controlled according to a thickness of an insulating material that is deposited for forming the spacers 137.

Referring to FIG. 3G, the source region S and the drain region D are formed by implanting impurities into the substrate 100 by using the gate electrode 130 as a mask. The impurities may be implanted at a desired (or alternatively predetermined) angle. Since the active region 120 that is exposed by the gate opening 140 is covered by the spacers 137, impurities may not be implanted in the current process.

Then, in order to form the semiconductor device 1000 of FIG. 2A, the interlayer insulating layer 150 may be formed on an entire surface of the resulting structure. The interlayer insulating layer 150 may fill an empty space of the gate opening 140, and may be formed on the gate electrode 130 to have a desired (or alternatively predetermined) thickness. Contact holes are formed by etching portions of the interlayer insulating layer 150, which are formed on the source region S and the drain region D, and the contact plugs 160 are formed by forming a conductive material within the contact holes, thereby completing the manufacture of the semiconductor device 1000 of FIG. 2A.

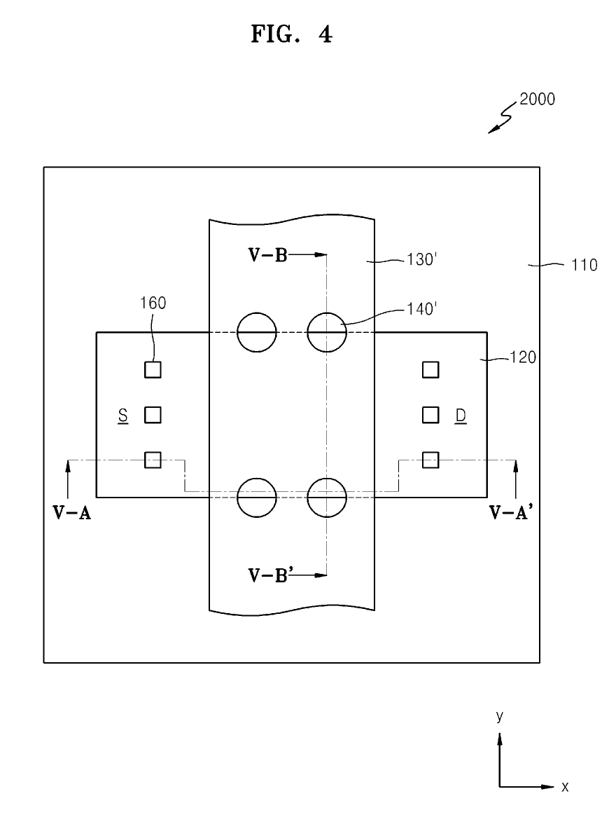

FIG. 4 is a schematic layout of a semiconductor device 2000 according to second embodiment of the inventive concept.

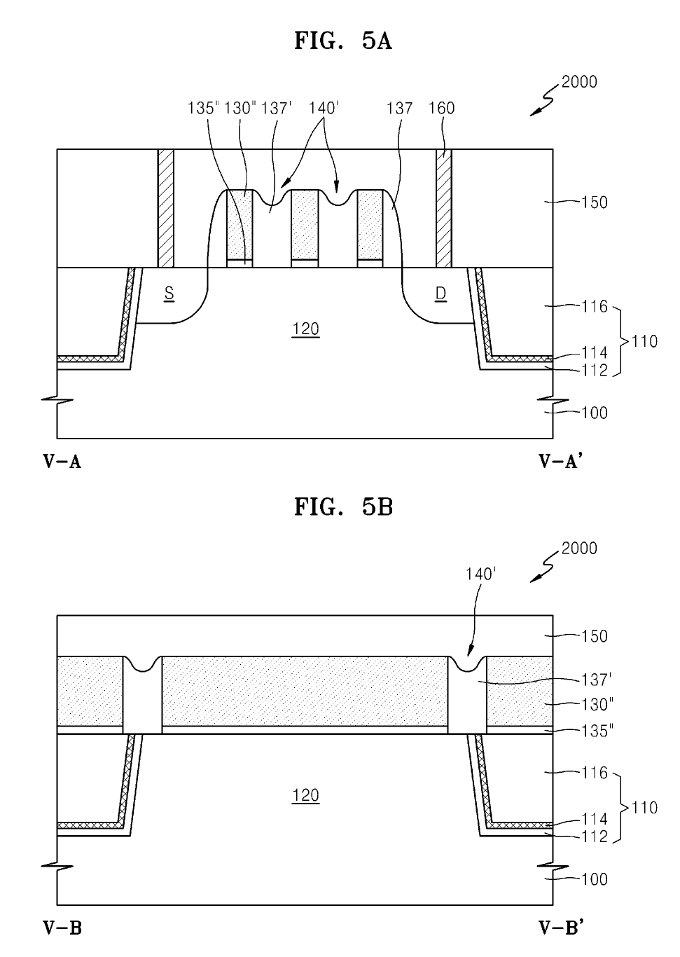

FIGS. 5A and 5B are cross-sectional views of semiconductor device 2000 taken along lines V-A-V-A′ and V-B-V-B′ of FIG. 4, respectively.

In FIGS. 4, 5A, and 5B, the same reference numerals as in FIGS. 1, 2A, and 2B denote the same components as in FIGS. 1, 2A, and 2B, and thus their detailed description will be omitted herein. Referring to FIGS. 4, 5A, and 5B, the semiconductor device 2000 includes the active region 120 that is defined by the device isolation layer 110 in the substrate 100. In addition, the semiconductor device 2000 may include the gate electrode 130″ disposed on the substrate 100 and including the gate opening 140′ formed therein, and the contact plugs 160 formed on the source region S and the drain region D that are formed at two sides of the gate electrode 130″. The gate dielectric layer 135″ may be between the gate electrode 130″ and the substrate 100.

The gate opening 140′ is formed through the gate electrode 130″. The gate opening 140′ may be a hole having a circular or oval sectional-view with a desired (or alternatively predetermined) diameter. A portion of the device isolation layer 110 and a portion of the active region 120 are exposed by the gate opening 140′. The gate openings 140′ may be symmetrically formed with respect to the active region 120 on the boundaries between the device isolation layer 110 and the active region 120 that are parallel to each other.

The gate openings 140′ may be formed on a single boundary between the device isolation layer 110 and the active region 120, which crosses the gate electrode 130″. For example, as shown in FIG. 4, two gate openings 140′ may be formed. The number of the gate openings 140′ may vary according to the size of the gate electrode 130″. A plurality of gate openings 140′ may be formed on the single boundary between the device isolation layer 110 and the active region 120 at desired (or alternatively predetermined) intervals.

The gate opening 140′ may be filled with an insulating material. For example, a lower portion of the gate opening 140′ may be filled with the spacer material 137′. That is, when the size of the gate opening is relatively small compared to the thickness of the spacer 137, the gate opening 140 is filled with a material for forming the spacer 137. In this case, the upper surface of the active region 120, which is exposed by the gate opening 140, may be completely covered by the spacers 137 and spacer material 137′.

In the semiconductor device 2000, the gate openings 140′ are formed in the gate electrode 130″, and thus the gate electrode 130″ may be formed intermittent along the channel region on the boundary between the active region 120 and the device isolation layer 110. Thus, an amount of a current is reduced at an edge of the active region 120, which corresponds to the boundary between the active region 120 and the device isolation layer 110 so that electrons are reduced (and/or prevented) from being trapped by the trench liner 114 by an operation of the semiconductor device 1000, thereby reducing the HEIP.

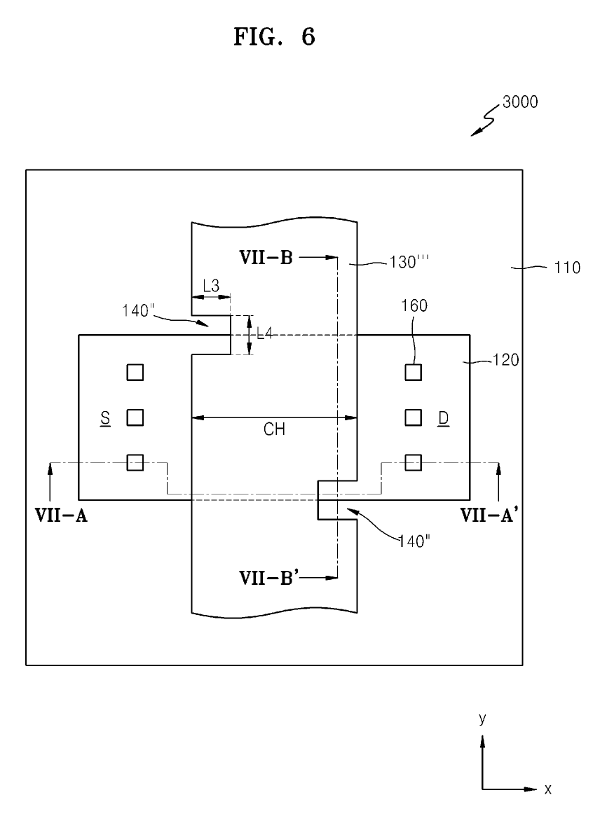

FIG. 6 is a schematic layout of a semiconductor device 3000 according to a third example embodiment of inventive concepts.

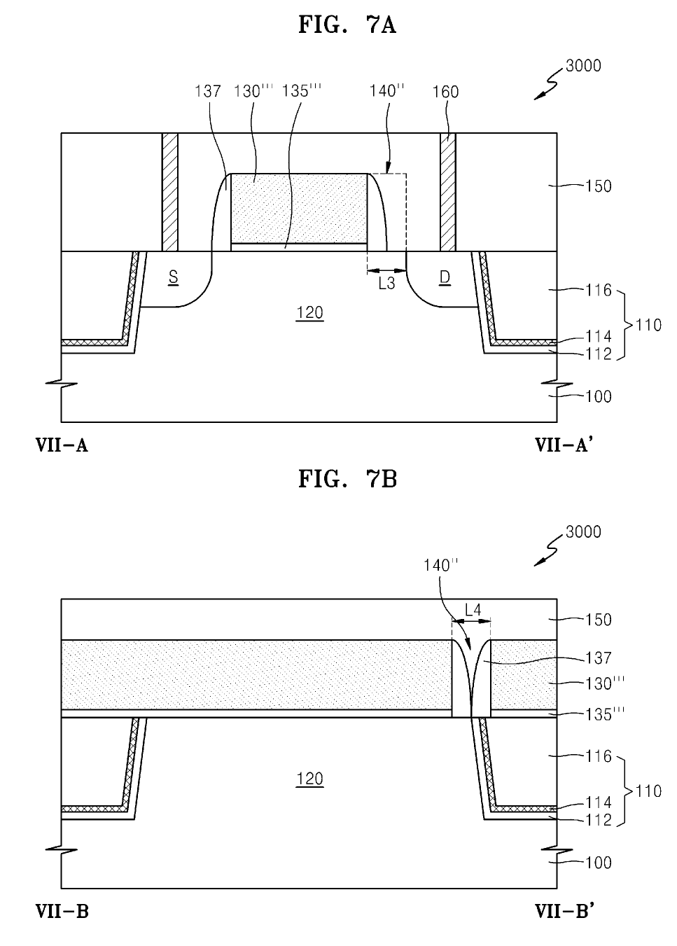

FIGS. 7A and 7B are cross-sectional views of semiconductor device 3000 taken along lines VII-A-VII-A′ and VII-B-VII-B′ of FIG. 6, respectively.

In FIGS. 6, 7A, and 7B, the same reference numerals as in FIGS. 1, 2A, and 2B denote the same components as in FIGS. 1, 2A, and 2B, and thus their detailed description will be omitted herein. Referring to FIGS. 6, 7A, and 7B, the semiconductor device 3000 includes the active region 120 that is defined by the device isolation layer 110 in the substrate 100. In addition, the semiconductor device 3000 may include the gate electrode 130″′ disposed on the substrate 100 and including the gate opening 140″ formed therein, and the contact plugs 160 formed on the source region S and the drain region D that are formed at two sides of the gate electrode 130. A gate dielectric layer 135″′ may be between the gate electrode 130″′ and the substrate 100.

The gate opening 140″ may be formed in a lateral surface of the gate electrode 130 to have a groove shape. The gate opening 140″ may be formed on a single boundary between the device isolation layer 110 and the active region 120, which crosses the gate electrode 130″′. A portion of the device isolation layer 110 and a portion of the active region 120 may be exposed by the gate opening 140″. The gate openings 140″ may be formed in opposite lateral surfaces of the gate electrode 130″′ on the boundaries between the device isolation layer 110 and the active region 120 that are parallel to each other. That is, the gate opening 140″ may be formed on a left lateral surface of the gate electrode 130″′ on one boundary between the device isolation layer 110 and the active region 120, and the gate opening 140″ may be formed on a right lateral surface of the gate electrode 130″′ on another boundary between the device isolation layer 110 and the active region 120.

The gate opening 140″ may be formed by removing from a lateral surface, that is, an edge of the gate electrode 130″′ inwards. The gate opening 140″ may have a third length L3 in the x-axis direction and a fourth length L4 in the y-axis direction. The third length L3 may be about ¼ to about ½ a channel length CH of the semiconductor device 3000. The third length L3 may be determined so as to sufficiently exhibit an intermittence effect of a channel region due to intermittence of the gate electrode 130″′. The fourth length L4 may be a desired (or alternatively predetermined) length so as to expose the boundary between the device isolation layer 110 and the active region 120, and may be determined so as not to excessively reduce an amount of a current of the semiconductor device 3000.

The gate opening 140″ may be filled and covered with an insulating material. For example, the spacers 137 may be formed on internal walls of the gate opening 140″, and an interlayer insulating layer 150 may fill and cover the remaining space. An upper surface of the active region 120, which is exposed by the gate opening 140″, may be completely covered by the spacers 137. Although one surface of the gate opening 140″ is not surrounded by the gate electrode 130, since the spacers 137 are formed on lateral walls of the gate electrode 130″′ surrounding the other surfaces of the gate opening 140″, the upper surface of the active region 120, which is exposed by the gate opening 140″, may be completely covered by the spacers 137. According to another example embodiment of inventive concepts, the upper surface of the active region 120, which is exposed by the gate opening 140″, may not be completely covered by the spacers 137.

The source region S and the drain region D may be formed at two sides of the gate electrode 130 in the active region 120. The source region S and the drain region D may be formed to have a desired (or alternatively predetermined) depth in the active region 120, and may each be an impurity region including impurities. According to the third example embodiment, the source region S and the drain region D may not be formed in the portion of the active region 120, which is exposed by the gate opening 140″. This is because impurities are not injected into the upper surface of the active region 120 in the gate opening 140″ during formation of the source region S and the drain region D since the upper surface of the active region 120 in the gate opening 140″ is completely covered by the spacers 137.

In the semiconductor device 3000, the gate openings 140 are formed in the gate electrode 130, and thus an amount of a current may be reduced at an edge of the active region 120. Thus, electrons are reduced (and/or prevented) from being trapped by the trench liner 114 by an operation of the semiconductor device 3000, thereby reducing the HEIP.

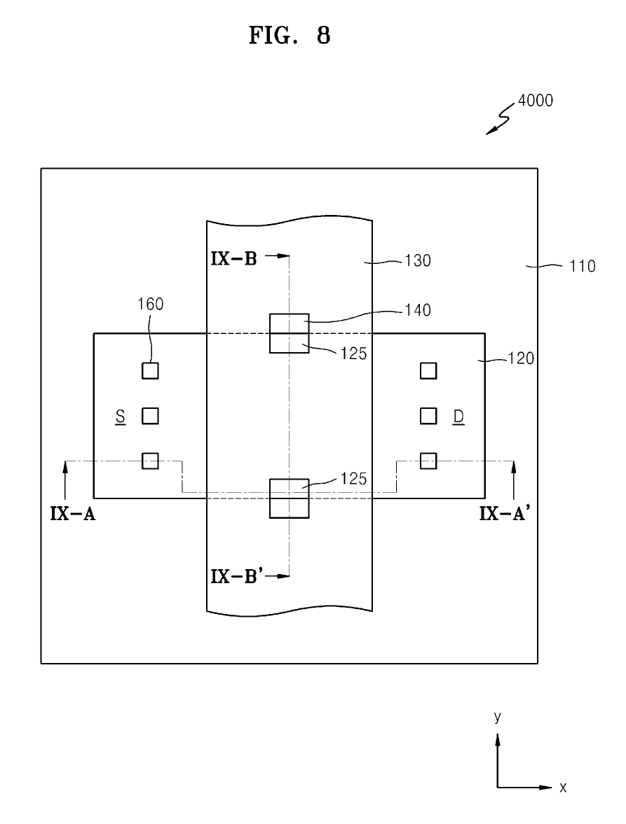

FIG. 8 is a schematic layout of a semiconductor device 4000 according to fourth example embodiment of inventive concepts.

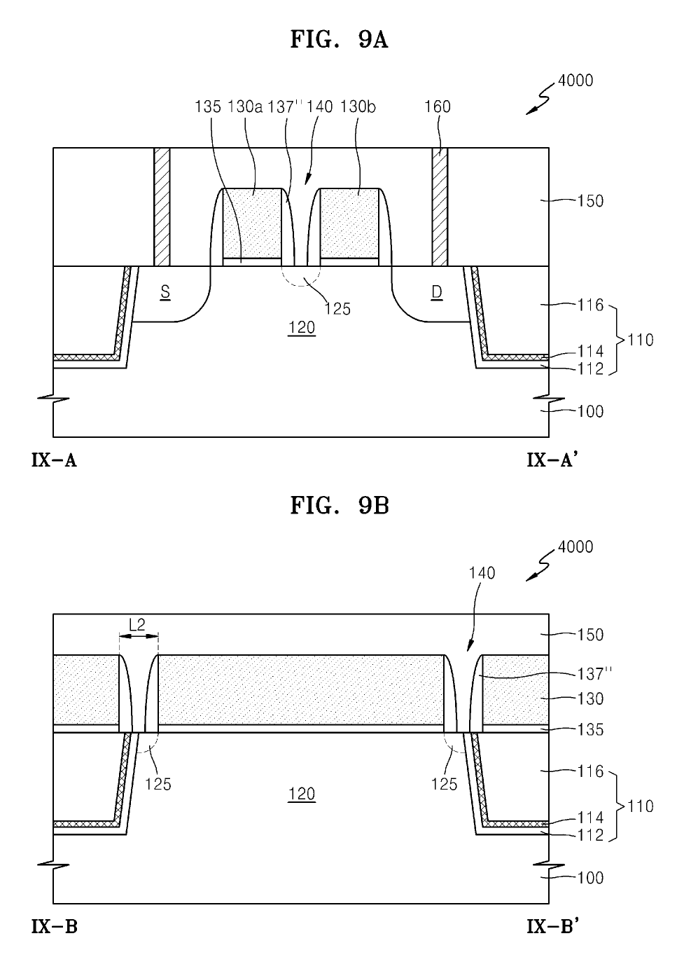

FIGS. 9A and 9B are cross-sectional views of semiconductor device 4000 taken along lines IX-A-IX-A′ and IX-B-IX-B′ of FIG. 8, respectively.

In FIGS. 8, 9A, and 9B, the same reference numerals as in FIGS. 1, 2A, and 2B denote the same components as in FIGS. 1, 2A, and 2B, and thus their detailed description will be omitted herein. Referring to FIGS. 8, 9A, and 9B, the semiconductor device 4000 includes the active region 120 that is defined by the device isolation layer 110 in the substrate 100. In addition, the semiconductor device 4000 may include the gate electrode 130 disposed on the substrate 100 and including the gate opening 140 formed therein, and the contact plugs 160 formed on the source region S and the drain region D that are formed at two sides of the gate electrode 130.

The gate opening 140 is formed through the gate electrode 130 in the gate electrode 130. The gate opening 140 may be formed on a boundary between the device isolation layer 110 and the active region 120, which crosses the gate electrode 130. A portion of the device isolation layer 110 and a portion of the active region 120 may be exposed by the gate opening 140. The gate openings 140 may be symmetrically formed with respect to the active region 120 on the boundaries between the device isolation layer 110 and the active region 120 that are parallel to each other.

The gate opening 140 may be filled and covered with an insulating material. For example, the spacers 137″ may be formed on internal walls of the gate opening 140, and an interlayer insulating layer 150 may fill and cover the remaining space. According to the fourth example embodiment, an upper surface of the active region 120, which is exposed by the gate opening 140, may not be completely covered by the spacers 137″.

An impurity region 125 may be formed on a portion of the active region 120, which is exposed by the gate opening 140. The impurity region 125 may include impurities of a different conductive type from in the source region S and the drain region D. For example, if the semiconductor device 4000 is a PMOS transistor, the impurity region 125 may include n-type impurities such as phosphorus (P), arsenic (As), or antimony (Sb). If the substrate 100 itself includes impurities, the impurity region 125 may be a region including impurities with a higher concentration than that of the substrate 100.

The impurity region 125 may be formed by performing an ion implantation process after a separate mask pattern is formed after one of the processes described with reference to FIGS. 3C, 3E, or 3F from among the processes described with reference to FIGS. 3A through 3G are performed. Thus, when the source region S and the drain region D are formed as described with reference to FIG. 3G, even if the same type of impurities as those of the source region S and the drain region D are injected into the upper surface of the active region 120, which is exposed by the gate opening 140, the same type of impurities may be compensated by the different type of impurities in the impurity region 125.

In the semiconductor device 4000, the gate opening 140 is formed in the gate electrode 130, and thus the gate electrode 130 may be formed intermittent along the channel region on the boundary between the active region 120 and the device isolation layer 110. Thus, an amount of a current is reduced at an edge of the active region 120, which corresponds to the boundary between the active region 120 and the device isolation layer 110 so that electrons are reduced (and/or prevented) from being trapped by the trench liner 114 by an operation of the semiconductor device 4000, thereby reducing the HEIP.

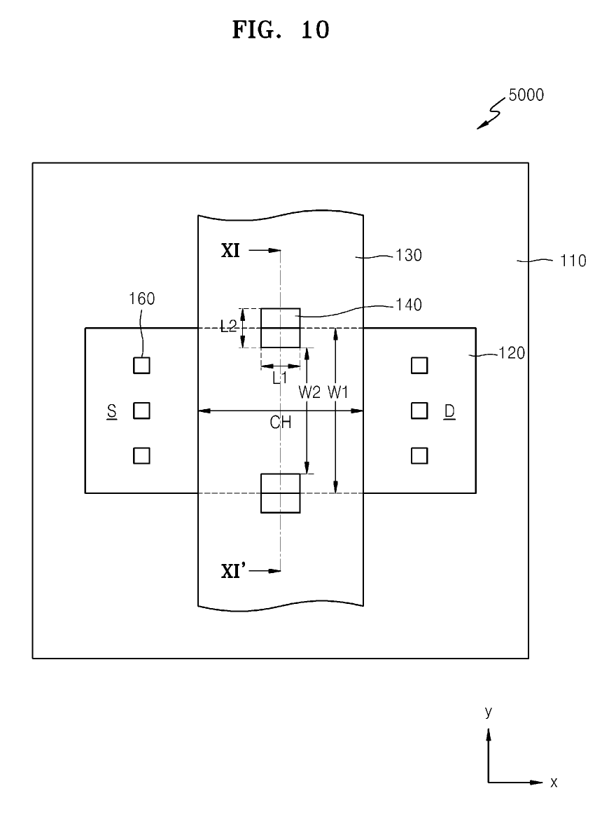

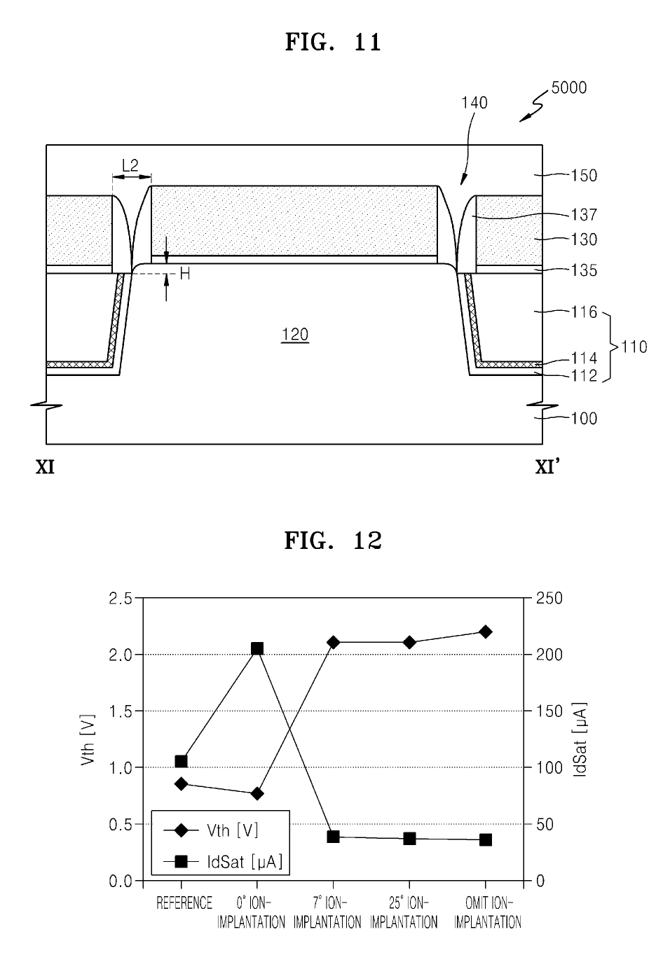

FIG. 10 is a schematic layer of a semiconductor device 5000 according to a fifth example embodiment of inventive concepts. FIG. 11 is a cross-sectional of semiconductor device 5000 semiconductor device 5000 taken along a line XI-XI′ of FIG. 1.

Referring to FIG. 10, the semiconductor device 5000 has the same plane structure as that of the semiconductor device 1000 of FIG. 1. The semiconductor device 5000 includes the active region 120 that is defined by the device isolation layer 110 in the substrate 100. In addition, the semiconductor device 5000 may include the gate electrode 130 disposed on the substrate 100 and including the gate opening 140 formed therein, and the contact plugs 160 (refer to FIG. 1) formed on the source region S and the drain region D that are formed at two sides of the gate electrode 130.

The semiconductor device 5000 is different from the semiconductor device 1000 described with reference to FIGS. 2A and 2B in that the active region 120 protrudes by a desired (or alternatively predetermined) height H compared to the device isolation layer 110. This structure may be formed by partially oxidizing edges of the active region 120 during formation of the device isolation layer 110, which has been described with reference to FIGS. 3A through 3C, and partially etching the device isolation layer 110 during a planarization process.

According to the fifth example embodiment, when the active region 120 protrudes compared to the device isolation layer 110 of the active region 120, if the gate opening 140 is not formed in the gate electrode 130, the edges of the active region 120 may largely affected by an electric field generated by the gate electrode 130. This is because the gate electrode 130 may be disposed on a lateral surface of the edge of the active region 120 as well as the upper surface of the active region 120. Thus, even if a relatively low gate voltage is applied to the edge of the active region 120, a current may flow through the edge of the active region 120, thereby reducing a threshold voltage of the semiconductor device 5000. In addition, as a channel width of the semiconductor device 5000 is reduced, the edges of the active region 120 may be more affected, and accordingly, a degree of reducing a threshold voltage may be increased. This is one of narrow width effects.

Regardless of whether the semiconductor device 5000 is a NMOS transistor or a PMOS transistor, the gate electrode 130 may be formed intermittent along the channel region on the boundary between the active region 120 and the device isolation layer 110. Thus, an amount of a current is reduced and a turn-on voltage is increased, at an edge of the active region 120, thereby avoiding reducing a threshold voltage of the semiconductor device 5000.

FIG. 12 is a graph showing a simulation result about characteristics of a semiconductor device according to an embodiment of the inventive concept.

Referring to FIG. 11 together with FIGS. 1 through 2B, the electrical characteristics of a PMOS transistor including the gate electrode 130 having a length of 300 nm are two-dimensionally simulated, and the simulation results are shown in FIG. 11. The source region S and the drain region D of the PMOS transistor have a desired (or alternatively predetermined) concentration by using an ion-implantation process. The simulation is performed when a voltage of 3 V is applied to the gate electrode 130 and the drain region D. In addition, the simulation is performed when the spacers 137 are not formed.

In the graph, ‘reference’ data corresponds to a case where the gate opening 140 is not formed, and the remaining data corresponds to cases where the gate opening 140 is formed along a channel in the middle of the gate electrode 130. An ion implantation angle at which an ion implantation process is performed in order to form the source region S and the drain region D may vary. The results are shown in the graph.

A threshold voltage Vth is illustrated as an absolute value thereof. When ion implantation is performed at a desired (or alternatively predetermined) angle and ion implantation is omitted, the threshold voltage Vth is increased compared to in the ‘reference’. However, the threshold voltage Vth is decreased compared to in the ‘reference’ only when the ion implantation is performed at 0°.

A saturation current Idsat is reduced compared to the ‘reference’ when ion implantation is performed at a desired (or alternatively predetermined) angle and ion implantation is omitted. However, the threshold voltage Vth is increased compared to in the ‘reference’ only when the ion implantation is performed at 0°. Both the threshold voltage Vth and the saturation current Idsat may not greatly vary according to an ion implantation angle or whether ion implantation is performed, except for a case where ion implantation is performed at 0°.

According to the simulation results, since the channel region is not continually formed between the source region S and the drain region D due to the gate opening 140, the threshold voltage Vth is increased, and the saturation current Idsat is reduced. Through this result, in the semiconductor device 1000, a current flowing through the active region 120 formed below the gate opening 140 may be reduced. Thus, electrons are reduced (and/or prevented) from being trapped by the trench liner 114, and the threshold voltage Vth may be reduced (and/or prevented) from being reduced at the edges of the active region 120.

However, when ion implantation is performed at 0°, since an impurity region including impurities having the same conductive type as the source region S and the drain region D is formed in the active region 120 formed below the gate opening 140, the threshold voltage Vth is reduced, and the saturation current Idsat is increased. In this case, according to some example embodiments of inventive concept, the spacers 137 are formed so as to reduce and/or prevent impurities from being injected, or the impurity region having a different conductive type from in the source region S and the drain region D is formed so as to obtain a corresponding effect.

While some example embodiments of inventive concepts have been particularly shown and described, it will be understood that various changes in form and detail may be made therein without departing from the spirit and scope of the claims.

What is claimed is:

1. A semiconductor device comprising:
a substrate;
a device isolation layer over the substrate, the device isolation layer defining an active region of the substrate;
a gate electrode crossing over the active region in between a source region and a drain region of the active region,
the gate electrode defining at least one gate opening,
the at least one gate opening exposing a portion of a boundary between the active region and the device isolation layer.

2. The semiconductor device of claim 1, further comprising: an insulating material filling the gate opening.

3. The semiconductor device of claim 1, further comprising:
spacers on at least two exterior lateral surfaces of the gate electrode and a lateral surface defining the gate opening.

4. The semiconductor device of claim 3, wherein
the spacers cover an upper surface of the active region that is exposed by the at least one gate opening.

5. The semiconductor device of claim 1, wherein
the at least one gate opening is a hole through the gate electrode.

6. The semiconductor device of claim 1, wherein
the gate electrode defines two gate openings,
the two gate openings are symmetrically positioned with respect to the active region on two boundaries between the device isolation layer and the active region.

7. The semiconductor device of claim 1, wherein
the gate electrode defines at least one gate opening on at least one lateral surface of the gate electrode.

8. The semiconductor device of claim 7, wherein
the gate electrode defines gate openings on opposite lateral surfaces of the gate electrode, and
the gate openings are over two boundaries between the device isolation layer and the active region.

9. The semiconductor device of claim 1, wherein
the gate electrode defines a plurality of gate openings over a boundary between the active region and the device isolation layer.

10. The semiconductor device of claim 1, wherein
the active region exposed by the at least one gate opening includes an impurity region, and
the impurity region includes impurities.

11. The semiconductor device of claim 10, wherein
the impurity region includes impurities with a different conductivity type than a conductivity type of impurities in the source region and the drain region.

12. The semiconductor device of claim 1, wherein
the device isolation layer includes a trench liner on a lateral wall of the substrate adjacent to the active region, and
the trench liner includes a nitride.

13. The semiconductor device of claim 1, further comprising:
a gate dielectric layer between the active region and the gate electrode.

14. A semiconductor device comprising:
a substrate;
a device isolation layer over the substrate, the device isolation layer defining an active region in the substrate; and a
a gate electrode crossing over a channel region of the active region in between a source region and a drain region of the active region,
the channel region including an upper surface having at least two different channel widths,
the at least two different channel widths extending in a direction parallel to an elongated direction of the gate electrode.

15. The semiconductor device of claim 14, wherein
the gate electrode defines at least one gate opening, the at least one gate opening exposes a portion of a boundary between the active region and the device isolation layer, and
the channel region has a smaller channel width in a region under where the at least one gate opening is defined than in a remaining region of the channel region that is not under where the at least one gate opening is defined.

16. A semiconductor device comprising:
a substrate including at least one active region defined by an isolation layer pattern,
the active region extending lengthwise in a first direction and widthwise in a second direction; and
a gate electrode extending in the second direction over the active region in between a source and drain region of the active region,
the gate electrode defining at least one gate opening,
the at least one gate opening exposing a part of the active region.

17. The semiconductor device of claim 16, wherein
the at least one gate opening is defined by at least one internal lateral surface of the gate electrode, and
the at least one gate opening exposes a portion of a boundary between the active region and the device isolation layer pattern.

18. The semiconductor device of claim 16, wherein
the at least one gate opening is defined by at least one external lateral surface of the gate electrode, and
the at least one gate opening exposes a portion of a boundary between the active region and the device isolation layer pattern.

19. The semiconductor device of claim 16, wherein
the gate electrode defines at least two gate openings that are spaced apart in the first direction, and
the at least two gate openings expose a first and a second portion of a boundary between the active region and the device isolation layer pattern.

20. The semiconductor device of claim 16, wherein
the gate electrode defines at least two gate openings that are spaced apart in the second direction,
the at least two gate openings expose a portion of a first boundary and a portion of a second boundary between the active region and the device isolation layer pattern.
